(19) United States
(12) Patent Application Publication
(10) Pub. No.: US 2014/0020744 A1
(43) Pub. Date: Jan. 23, 2014

(54) USING AMORPHOUS ZINC-TIN OXIDE ALLOYS IN THE EMITTER STRUCTURE OF CIGS PV DEVICES

(71) Applicants: Alliance for Sustainable Energy, LLC, Golden, CO (US); HelioVolt Corporation, Austin, TX (US)

(72) Inventors: Peter Hersh, Denver, CO (US); Maikel van Hest, Denver, CO (US); David Ginley, Evergreen, CO (US); John Perkins, Boulder, CO (US); Vincent Bollinger, Arvada, CO (US)

(21) Appl. No.: 13/733,784

(22) Filed: Jan. 3, 2013

Related U.S. Application Data
(60) Provisional application No. 61/631,390, filed on Jan. 3, 2012.
(60) Provisional application No. 61/689,406, filed on Jun. 5, 2012.

(51) Int. Cl. H01L 31/0224; H01L 31/18

(52) U.S. Cl. CPC H01L 31/022466; H01L 31/1884
USPC 136/256; 204/192.29; 423/593.1; 423/594.9; 252/519.1

(57) ABSTRACT

A device includes a back contact, an absorber layer coupled to the back contact, a buffer layer coupled to the absorber layer; and an amorphous transparent conductive layer coupled to the buffer layer, wherein the amorphous transparent conductive phase is characterized by, as a function of composition, i) a range of band gaps and ii) a range of work functions.

### CROSS-REFERENCES TO RELATED APPLICATIONS

This application claims a benefit of priority under 35 U.S.C. 119(e) from both copending provisional patent application U.S. Ser. No. 61/631,390, filed Jan. 3, 2012 and copending provisional patent application U.S. Ser. No. 61/689,406, filed Jun. 5, 2012, the entire contents of both of which are hereby expressly incorporated herein by reference for all purposes.

### STATEMENT AS TO RIGHTS MADE UNDER FEDERALLY-SPONSORED RESEARCH OR DEVELOPMENT

The United States Government has rights in this invention under Contract No. DE-AC36-08GO28308 between the United States Department of Energy and the Alliance for Sustainable Energy, LLC, the Manager and Operator of the National Renewable Energy Laboratory. This invention was made under a CRADA # CRD-03-121 between HelioVolt Corporation and the National Renewable Energy Laboratory operated for the United States Department of Energy.

### BACKGROUND INFORMATION

The most commonly used structure for a CIGS photovoltaic device utilizes a crystalline zinc oxide layer between the cadmium sulfide buffer layer and the transparent conducting oxide.

Amorphous Zinc-Tin Oxide has been studied for potential use as channel layers in thin-film transistors, and for its properties as a transparent conducting oxide (TCO). Zinc tin oxide has many attractive attributes such as a smooth scratch resistant surface, resistance to etching, and chemical stability with respect to oxidation.

### SUMMARY

There is a need for the following embodiments. According to one embodiment of the present disclosure, a process comprises: forming an amorphous transparent conductive layer on a photovoltaic buffer layer, wherein the amorphous transparent conductive phase is characterized by, as a function of composition, i) a range of band gaps and ii) a range of work functions. According to another embodiment of the present disclosure, a manufacture comprises: a back contact, an absorber layer coupled to the back contact, a buffer layer coupled to the absorber layer; and an amorphous transparent conductive layer coupled to the buffer layer, wherein the amorphous transparent conductive phase is characterized by, as a function of composition, i) a range of band gaps and ii) a range of work functions. According to another embodiment of the present disclosure, a composition of matter comprises: an amorphous transparent conductive phase, wherein the amorphous transparent conductive phase is characterized by, as a function of composition, i) a range of band gaps and ii) a range of work functions.

These, and other, embodiments described herein will be better appreciated and understood when considered in conjunction with the following description and the accompanying drawings. It should be understood, however, that the following description, while indicating various embodiments and numerous specific details thereof, is given for the purpose of illustration and does not imply limitation. Many substitutions, modifications, additions and/or rearrangements may be made within the scope of embodiments, and additional embodiments include all such substitutions, modifications, additions and/or rearrangements.

### BRIEF DESCRIPTION OF THE DRAWINGS

The drawings accompanying and forming part of this specification are included to depict certain embodiments. A clearer concept of embodiments described in this application will be readily apparent by referring to the exemplary, and therefore nonlimiting, embodiments illustrated in the drawings (wherein identical reference numerals (if they occur in more than one view) designate the same elements). The described embodiments may be better understood by reference to one or more of these drawings in combination with the following description presented herein. It should be noted that the features illustrated in the drawings are not necessarily drawn to scale.

FIG. 1. is a view of work function versus composition for embodiment deposited by DC reactive and RF Ceramic sputtering;

FIG. 2. is a schematic of ZnO, CdS and amorphous Zinc-Tin-Oxide (ZTO) band alignment including work functions (Φ) and band gaps (Eg). For ZTO, the dashed double headed arrow lines denote DC sputtered film with 35% cation zinc; the dotted double headed arrow lines denote RF sputtered film with 80% cation zinc;

FIG. 3. is a graphic of band alignment for reactively DC sputtered zinc tin oxide compared to zinc oxide and cadmium sulfide. The work function and band gap are measured; the Fermi level is assumed to be in the middle of the band gap;

FIG. 4. is a graphic of band alignment for RF magnetron sputtering from ceramic targets of zinc tin oxide compared to zinc oxide and cadmium sulfide. Again, the work function and band gap are measured; the Fermi level is assumed to be in the middle of the band gap;

FIG. 5. is a cross-sectional image of a CIGS thin film solar cell with amorphous zinc tin oxide in place of zinc oxide; and

FIG. 6 is a flow chart of a process for forming an amorphous transparent conductive layer on a photovoltaic buffer layer followed by forming a transparent conductive oxide layer on the amorphous transparent conductive layer.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well known starting materials, processing techniques, components and equipment are omitted so as not to unnecessarily obscure the embodiments' details. It should be understood, however, that the detailed description and the specific examples, are given by way of illustration only and not by way of limitation. Various substitutions, modifications, additions and/or rearrangements within the scope of the underlying inventive concept will become apparent to those skilled in the art from this disclosure.

One or more of the embodiments described in the present application utilize amorphous zinc tin oxide in place of zinc oxide in CIGS photovoltaic devices. Using amorphous zinc tin oxide in the GIGS device structure offers potential benefits over zinc oxide, which include improved chemical stability, an amorphous nature which could lead to a more conformal coating, a wider band gap, and the ability to tune bandgap, Fermi level, and band alignment at its heteroface with other constituents of the emitter structure. A more conformal coating can potentially reduce the amount of shunting in the device with a thinner layer. A wider band gap allows for transmission of more light, potentially increasing photocurrent generation. The ability to tune the bands provides flexibility to tailor band alignment to match alternative buffers optimized for different gallium ratios at the CIGS junction.

The typical GIGS device structure employs a molybdenum back contact and a CdS/ZnO/ZnO:Al emitter structure. In accordance with one embodiment, the undoped ZnO is replaced with amorphous zinc-tin oxide alloys (ZTO). Varying composition and deposition method of the ZTO can provide a wide range of band gap (3.3-3.9 eV) and work function (4.3-5.2 eV), while remaining amorphous. The flexibility of the ZTO provides the opportunity to tune the bands to optimize band-edge and Fermi level alignment. Devices demonstrated to date with ZTO alloy composition have yielded a maximum efficiency of 11.9% with an average of 11.3%, which is very similar to comparable devices with undoped ZnO that have a maximum efficiency of 12.0% with an average of 11.3%.

Films for characterization of zinc tin oxide were deposited via a combinatorial approach using two different methods, reactive DC sputtering from metal targets and a RF magnetron sputtering from ceramic targets. The films were deposited on glass to measure their composition via X-ray fluorescence and optical properties using transmission-reflection. Band gaps were calculated from optical data and are used in the determination of the conduction band offsets. Films were deposited onto a transparent conductive oxide (TCO) material to measure their work functions using a Kelvin point probe. All films were deposited at room temperature.

In one embodiment for devices, zinc tin oxide films are deposited using a single target on top of a Mo/CIGS/CdS stack. The devices were finished with subsequent deposition of TCO and grids, and then tested using an AM 1.5G simulator.

A. Zinc Tin Oxide Film Characterization

A range of compositions has been explored using the combinatorial deposition approach. Films had a composition that varied from 20 to 80 cation % zinc as measured by XRF. All the films in that composition range were found to be amorphous. The films in this range varied in band gap from 3.3 eV for 20 cation % zinc to 3.9 eV for 80 cation % zinc. No significant difference in crystallinity or optical properties was observed between the reactive DC and RF magnetron sputtering methods.

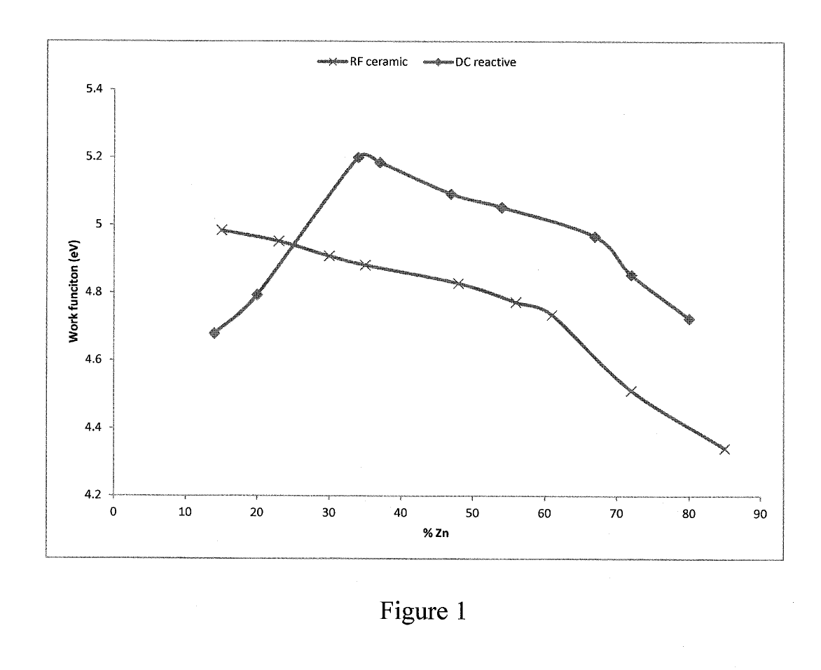

A work function was measured using a Kelvin point probe and showed a range of values from 4.3 to 5.2 eV depending on composition and deposition method as shown in FIG. 1. The DC reactive sputtered films have a deeper work function than the films deposited using RF sputtering over most of the composition range. The RF-sputtered films trend monotonically to a shallower work function with increasing zinc, but the reactive films' work function gets deeper up to 35 cation % zinc, then gets shallower with more zinc.

The difference in work function between the RF and DC sputtered films could be caused by a difference in composition or short range order depending on deposition method. zinc oxide has a work function ˜4.5 eV with a band gap ˜3.4 eV.

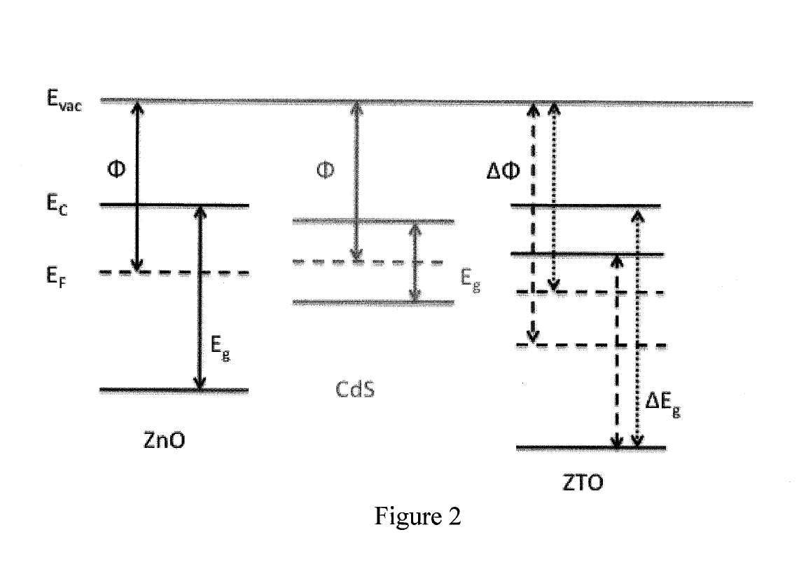

FIG. 2 shows a schematic of ZnO, CdS and Zinc-Tin-Oxide (ZTO) band position including work functions (Φ) and band gaps (Eg) of all of the materials. E_{vac}=vacuum level, E_{f}=Fermi level, and E_{c}=conduction band level, for one embodiment. While ZnO and CdS have well-defined band gaps and work functions, ZTO has a range of band gaps and work functions depending on its composition. This can allow for fine-tuning of the material properties to ideally match CdS or alternative buffer materials.

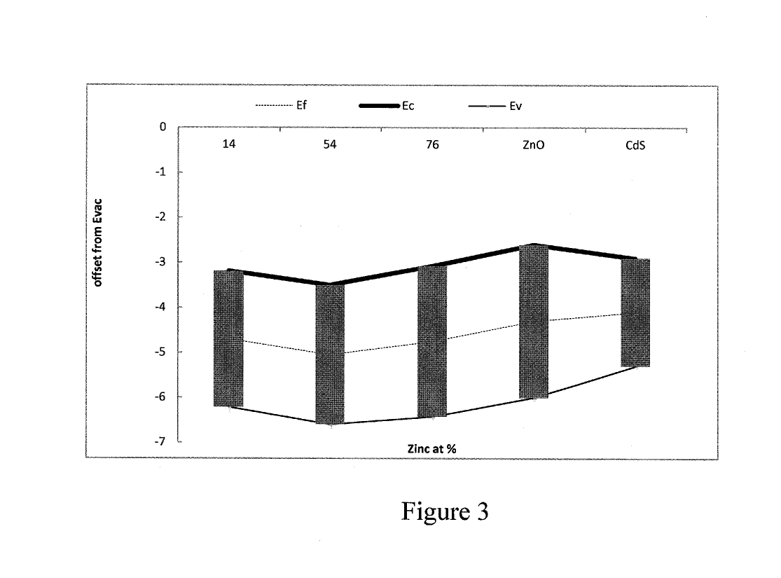

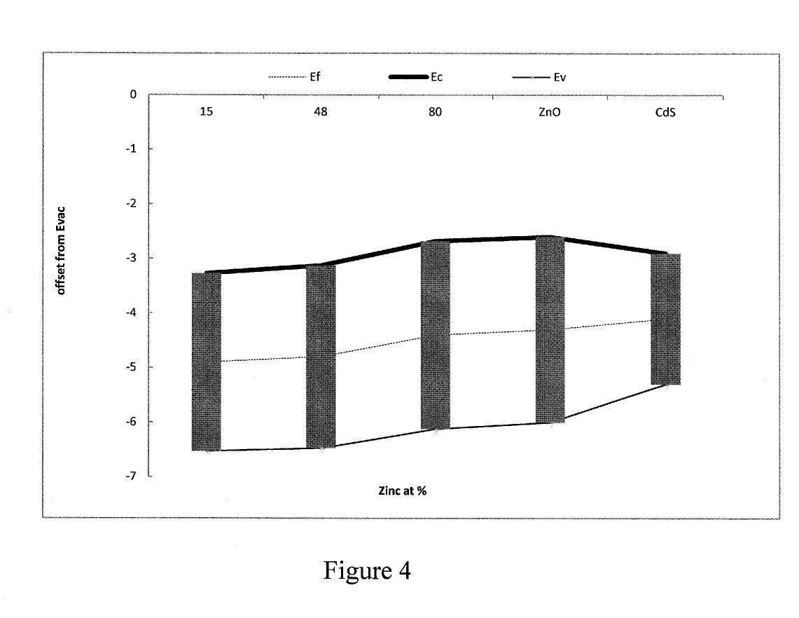

The range of the band positions for ZTO offers many different band offsets with the CdS. The deepest work function and conduction band minimum correspond to a DC sputtered film with 35 cation % zinc. The shallowest work function and conduction band minimum correspond to a RF sputtered film with 80 cation % zinc. All other ZTO films fall in between these two films allowing for tuning. This tuning accommodates tuning the conduction band offset and to explore optimization with other buffers materials. FIGS. 3 and 4 demonstrate band alignment for different ZTO compositions for reactive DC sputtering and ceramic RF sputtering, respectively.

FIGS. 2-4 assume that the material is completely intrinsic with the Fermi level found in the middle of the band gap. For precisely aligned bands, the ZTO conduction band should align with the CdS conduction band. This will allow for the maximum open circuit voltage without losing current from carrier reflection at their heteroface. Given these assumptions the ideal band alignment occurs at 80 cation % zinc for DC reactive sputtering and at 65 cation % zinc for RF ceramic sputtering.

B. Devices with Zinc Tin Oxide

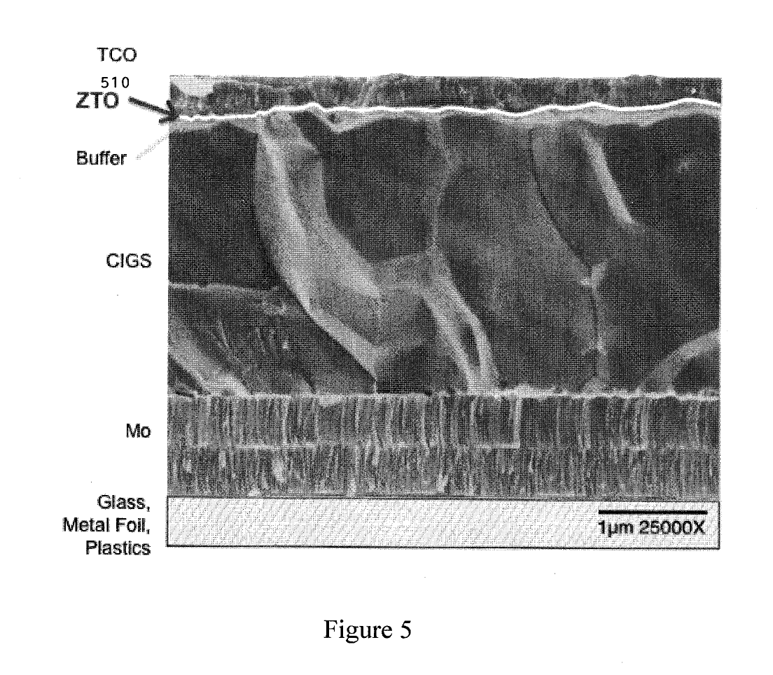

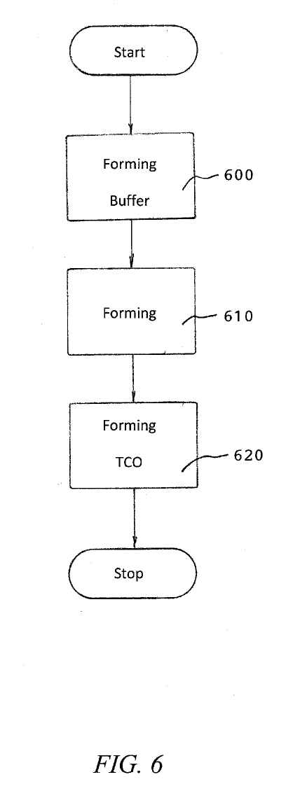

Films of zinc tin oxide were put on CdS in the CIGS photovoltaic stack. FIG. 5 shows a picture of a CIGS stack with ZTO in place of ZnO. FIG. 5 illustrates a device including a substrate (e.g. glass, metal foil, plastics), a back contact (e.g. Mo), an absorber layer coupled to the back contact (e.g. CIGS), a buffer layer coupled to the absorber layer; and an amorphous transparent conductive layer 510 coupled to the buffer layer, wherein the amorphous transparent conductive layer is characterized by, as a function of composition, i) a range of band gaps and ii) a range of work functions. FIG. 6 illustrates forming 600 a photovoltaic buffer layer, then forming 610 an amorphous transparent conductive layer on the photovoltaic buffer layer; and then forming 620 a transparent conductive oxide layer on the amorphous transparent conductive layer, wherein the amorphous transparent conductive layer is characterized by, as a function of composition, i) a range of band gaps and ii) a range of work functions. These ranges can be obtained without doping (providing electron and/or hole donor impurities) because of the characteristics of the intrinsic amorphous transparent conductive layer. For instance, amorphous zinc tin oxide can be characterized as a function of the composition varying from a Zn:Sn ratio of 20 cation % Zn:80 cation % Sn to a Zn:Sn ratio of 80 cation % Zn:20 cation % Sn by the range of work functions substantially as shown in FIG. 1. Similarly, amorphous zinc tin oxide can be characterized as a function of the composition varying from a Zn:Sn ratio of 14 cation % Zn:86 cation % Sn to a ZN:Sn ratio of 76 cation % Zn:24 cation % Sn by the range of band gaps substantially as shown in FIG. 3 or 4, which figure depending on the sputtering deposition methodology.

The device results shown in Table 1 are all from the same panel of CIGS with the same CBD CdS layer all the devices were finished off with the same TCO and grids and made into 0.43 cm² devices for testing. Table 1 shows the device results from different deposition methods RF magnetron and reactive DC sputtering. The table also shows the effects of completely removing the intrinsic layer and the use of different intrinsic layers ZnO and ZTO at two different compositions. All of the intrinsic layers were deposited to ˜50 nm.

TABLE I
SUMMARY OF INTRINSIC LAYERS ON CIGS

| Sputter | | | | | | | | |
|---|---|---|---|---|---|---|---|---|
| type | Intrinsic layer | Type | Eff % | Voc (mV) | Jsc (mA/cm²) | FF % | Rs (ohms) | Gsh (S) |
| NA | None | AVG | 8.2 | 552 | 29.5 | 53.1 | 6.7 | 0.0029 |
| | | Champ | 10 | 545 | 31.5 | 58 | 5.8 | 0.0019 |
| Ceramic | ZnO | AVG | 11.3 | 593 | 30.6 | 63 | 4 | 0.0022 |
| RF | | Champ | 12 | 602 | 30.6 | 65 | 3.9 | 0.003 |
| | 80 cation % | AVG | 10.6 | 595 | 30.3 | 59.1 | 6.3 | 0.0021 |
| | Zn ZTO | Champ | 10.8 | 592 | 30.8 | 59.1 | 5 | 0.0016 |
| Reactive | ZnO | AVG | 10.2 | 607 | 30.2 | 56.1 | 5.9 | 0.0021 |
| DC | | Champ | 11.9 | 606 | 31.3 | 62.5 | 6.5 | 0.0014 |
| | 55 cation % | AVG | 9.5 | 589 | 29 | 56.7 | 6.9 | 0.0021 |
| | Zn ZTO | Champ | 11 | 599 | 30.7 | 59.6 | 6.1 | 0.0014 |
| | 80 cation % | AVG | 11.3 | 612 | 30 | 61.2 | 5.7 | 0.0024 |
| | Zn ZTO | Champ | 11.9 | 612 | 31.6 | 31.3 | 3.8 | 0.0033 |

The two different compositions of ZTO intrinsic layers deposited via reactive DC show that improving the conduction band alignment yields improved device results. The conduction band offset (CBO) from the CdS buffer layer for the 55 cation % Zn ZTO is ˜0.5 eV. For the 80 cation % Zn ZTO the CBO is ˜0 eV. The 80 cation % Zn ZTO devices have better Voc, Jsc and FF when compared to the 55 cation % Zn ZTO devices.

The best results for the ZTO intrinsic layer come with the inclusion of 80 cation % Zn ZTO deposited using reactive DC sputtering. The average device for this deposition method has a conversion efficiency of 11.3%. The best device has a conversion efficiency of 11.9%. This result is very comparable to the best results achieved for ZnO using RF magnetron sputtering, which has an average conversion efficiency of 11.3% with a champion efficiency of 12%

The RF magnetron sputtering of gave better results with the ZnO when compared to the 80 cation % Zn ZTO. The main difference between the devices with ZTO and the devices with ZnO is the fill factor, which can be linked to a lower series resistance in the devices with the ZnO intrinsic layer. The higher series resistance seen in the ZTO devices could be linked to a non-optimized ZTO deposition.

There is a clear drop in conversion efficiency between RF deposited ZnO and reactive DC sputtered ZnO. The ZTO intrinsic layers show the reverse trend with the reactive DC showing the improved results over the RF sputtered layer. The reasons for the changes in efficiency between RF magnetron and reactive DC for both ZTO and ZnO intrinsic layers have not been determined.

This exploratory demonstration of amorphous zinc tin oxide (ZTO) in lieu of undoped crystalline zinc oxide in a CIGS solar cell shows promise. ZTO offers improved chemical stability to oxygen [iv], a smooth surface and potentially provides a more conformal coating of CIGS. Work function and band gap of the amorphous ZTO can be tuned by changing the composition. With this tunability the conduction band offset can be optimized for a wide range of buffer materials. Preliminary device results gave a 11.3% average efficiency using ZTO from a Zn:Sn metal target with a 80 cation %:20 cation % composition, compared to 11.3% average using conventional ZnO.

### Definitions

The term phase is intended to mean a region of space (in a thermodynamic system) throughout which all physical properties of a material are essentially uniform. The phrase cation content is intended to mean the percentage or relative amount of a given cation of interest (relative to total cations) in a given volume or mass of interest. The term absorber is intended to mean the photon absorbing portion of a photovoltaic. The term buffer is intended to mean the junction forming region of a photovoltaic. The term emitter is intended to mean the electron emitting, hole collecting portion of a photovoltaic. The term amorphous transparent conductive layer is intended to mean a non-crystalline, substantially photon transparent, electronically conducting portion of a photovoltaic. The term back contact is intended to mean the hole emitting, electron collecting portion of a photovoltaic. The term work function is intended to mean the energy difference between the vacuum level and Fermi level of a material in a photovoltaic. The term photovoltaic is intended to mean an article of manufacture for the generation of a voltage when radiant energy falls on the boundary between dissimilar substances (as two different semiconductors). The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

Unless otherwise defined, all technical and scientific terms used herein have the same meaning as commonly understood by one of ordinary skill in the art. In case of conflict, the present specification, including definitions, will control.

The described embodiments and examples are illustrative only and not intended to be limiting. Although embodiments disclosed herein can be implemented separately, they may also be integrated into the system(s) with which they are associated. All the embodiments disclosed herein can be made and used without undue experimentation in light of the disclosure. Although the best mode contemplated by the inventor(s) is disclosed, embodiments are not limited thereto. Embodiments are not limited by theoretical statements (if any) recited herein. The individual steps of embodiments need not be performed in the disclosed manner, or combined in the disclosed sequences, but may be performed in any and all manner and/or combined in any and all sequences. The individual components of embodiments need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials. Homologous replacements may be substituted for the substances described herein.

Various substitutions, modifications, additions and/or rearrangements of the features of embodiments may be made without deviating from the scope of the underlying inventive concept. All the disclosed elements and features of each disclosed embodiment can be combined with, or substituted for, the disclosed elements and features of every other disclosed embodiment except where such elements or features are mutually exclusive.

The appended claims are not to be interpreted as including means-plus-function limitations, unless such a limitation is explicitly recited in a given claim using the phrase(s) “means for” and/or “step for.” Subgeneric embodiments are delineated by the appended independent claims and their equivalents. Specific embodiments are differentiated by the appended dependent claims and their equivalents.

What is claimed is:

1. A composition of matter, comprising:
an amorphous transparent conductive phase, wherein the amorphous transparent conductive phase is characterized by, as a function of composition, i) a range of band gaps and ii) a range of work functions.

2. The composition of matter of claim 1, wherein the amorphous transparent conductive phase includes zinc, tin and oxygen and is an intrinsic semiconductor.

3. The composition of matter of claim 2, wherein a cation content of the amorphous transparent conductive phase includes from approximately 20 cation % Zn to approximately 80 cation % Zn.

4. The composition of matter of claim 3, wherein the cation content of the amorphous transparent conductive phase includes approximately 80 cation % Zn.

5. The composition of matter of claim 3, wherein the cation content of the amorphous transparent conductive phase includes approximately 65 cation % Zn.

6. An apparatus, comprising:
a device including a back contact, an absorber layer coupled to the back contact, a buffer layer coupled to the absorber layer; and an amorphous transparent conductive layer coupled to the buffer layer;
wherein the amorphous transparent conductive layer is characterized by, as a function of composition, i) a range of band gaps and ii) a range of work functions.

7. The apparatus of claim 6, wherein the amorphous transparent conductive phase includes zinc, tin and oxygen and is an intrinsic semiconductor.

8. The apparatus of claim 7, wherein a cation content of the amorphous transparent conductive phase includes from approximately 20 cation % Zn to approximately 80 cation % Zn.

9. The apparatus of claim 8, wherein the cation content of the amorphous transparent conductive phase includes approximately 80 cation % Zn.

10. The apparatus of claim 8, wherein the cation content of the amorphous transparent conductive phase includes approximately 65 cation % Zn.

11. A method, comprising:
forming an amorphous transparent conductive layer on a photovoltaic buffer layer, wherein the amorphous transparent conductive layer is characterized by, as a function of composition, i) a range of band gaps and ii) a range of work functions.

12. The method of claim 11, wherein the amorphous transparent conductive phase includes zinc, tin and oxygen and is an intrinsic semiconductor.

13. The method of matter of claim 12, wherein a cation content of the amorphous transparent conductive phase includes from approximately 20 cation % Zn to approximately 80 cation % Zn.

14. The method of claim 11, wherein forming includes depositing.

15. The method of claim 14, wherein depositing includes sputtering.

16. The method of claim 15, wherein sputtering includes reactive DC sputtering of a metal target.

17. The method of claim 16, wherein a cation content of the amorphous transparent conductive phase includes approximately 80 cation % Zn.

18. The method of claim 15, wherein sputtering includes RF sputtering of a ceramic target.

19. The method of claim 18, wherein a cation content of the amorphous transparent conductive phase includes approximately 65 cation % Zn.
